(19) United States
(12) Patent Application Publication
(10) Pub. No.: US 2014/0124910 A1
(43) Pub. Date: May 8, 2014

(54) SEMICONDUCTOR PACKAGE AND METHOD OF FORMING THE SAME

(71) Applicant: Byung-Woo LEE, Hwasung-city (KR)

(72) Inventor: Byung-Woo LEE, Hwasung-city (KR)

(21) Appl. No.: 14/060,910

(22) Filed: Oct. 23, 2013

(30) Foreign Application Priority Data
Nov. 8, 2012 (KR) 10-2012-0125999

(51) Int. Cl. H01L 23/00; H01L 23/495

(52) U.S. Cl. CPC H01L 24/33; H01L 23/4952
USPC 257/668

(57) ABSTRACT

Semiconductor packages and methods of forming the same may be provided. According to the semiconductor package of the present inventive concepts, a bump attached to and protruded from a bonding pad on a surface of a semiconductor chip is inserted into a through-hole defined in a package substrate. As a result, a thickness of the semiconductor package may be reduced by at least a height of the bump. Because an empty space does not exist between a semiconductor chip and the package substrate, the semiconductor package does not need a conventional underfill resin layer. Accordingly, processes of forming the semiconductor package may be simplified.

### CROSS-REFERENCE TO RELATED APPLICATIONS

This U.S. non-provisional patent application claims priority under 35 U.S.C. §119 to Korean Patent Application No. 10-2012-0125999, filed on Nov. 8, 2012, the entirety of which is incorporated by reference herein.

### BACKGROUND

The inventive concepts relate to semiconductor packages and methods of forming the same.

Higher performance, higher speed, and smaller size of electronic parts have been increasingly demanded in the electronics industry. Various mounting techniques of semiconductor packages have been conducted to meet these demands. A flip chip bonding method realizes a very short connection distance between pads as than a wire bonding method. Thus, a signal transmission speed may be improved. Additionally, a short of wires does not occur in the flip chip bonding method. However, a void may exist between bumps in a semiconductor package formed by the flip chip bonding method. An underfill resin layer may be formed to fill a space between the bumps such that the void may be prevented or mitigated. In this case, a dam may be required to prevent a flow of the underfill resin solution. Accordingly, it may be difficult to reduce horizontal and vertical sizes of the semiconductor package.

### SUMMARY

Example embodiments of the inventive concepts may provide highly integrated semiconductor packages.

Example embodiments of the inventive concepts may also provide methods of forming a semiconductor package capable of simplifying processes.

According to example embodiments, a semiconductor package may include a package substrate including at least one through-hole and a lower conductive pattern, the through-hole penetrating the package substrate, and the lower conductive pattern disposed on a bottom surface of the package substrate, a first semiconductor chip mounted on the package substrate, the first semiconductor chip including a bonding pad, and a first solder pattern disposed in the through-hole, the first solder pattern electrically connecting the bonding pad to the lower conductive pattern.

The first semiconductor chip may further include a bump attached to the bonding pad and inserted in the through-hole.

A diameter of the through-hole may be greater than a diameter of the bump disposed in the through-hole.

The lower conductive pattern may extend to cover an inner sidewall of the through-hole, and the first solder pattern may fill a space between the lower conductive pattern and the bump.

The first solder pattern may be in contact with an inner sidewall of the through-hole and the lower conductive pattern.

The semiconductor package may further include a mold layer covering at least a sidewall of the first semiconductor chip.

The mold layer may include a mold through-hole penetrating the mold layer. The package substrate may further include an upper conductive pattern disposed on a top surface of the package substrate and exposed by the mold through-hole. In this case, the semiconductor package may further include a second semiconductor chip disposed on the first semiconductor chip, the second semiconductor chip including a second bonding pad overlapping with the mold through-hole, and a second solder pattern in the mold through hole, the second solder pattern electrically connecting the second bonding pad to the upper conductive pattern in the mold through-hole.

The second semiconductor chip may further include a bump contacting the second bonding pad and the second solder pattern. The bump of the second semiconductor chip may be inserted in the mold through-hole.

The semiconductor package may further include an adhesive layer disposed between the package substrate and the first semiconductor chip.

The semiconductor package may further include an external solder ball bonded to the lower conductive pattern. A protruded end of the first solder pattern may be higher than a bottom end of the external solder ball, the bottom end of the external solder ball being an end contacting the lower conduction pattern.

According to example embodiments, a semiconductor package may include a first semiconductor package including a first package substrate and a first semiconductor chip disposed on the first package substrate, the first package substrate including a first through-hole, and the first semiconductor chip including a first bump inserted in the first through-hole, and a second semiconductor package stacked on the first semiconductor package, the second semiconductor package including a second package substrate and a second semiconductor chip disposed on the second package substrate, the second package substrate including a second through-hole, and the second semiconductor chip including a second bump inserted in the second through-hole.

According to example embodiments, a method of forming a semiconductor package may include preparing a package substrate including a through-hole and a lower conductive pattern; mounting a first semiconductor chip including a bonding pad on the package substrate, the bonding pad disposed at a position corresponding to the through-hole on the package substrate, and forming a first solder pattern electrically connecting the bonding pad to the lower conductive pattern in the through-hole.

The first semiconductor chip may further include forming a bump on the bonding pad such that the bump is protruded from the bonding pad. Mounting the first semiconductor chip on the package substrate may include inserting the bump of the first semiconductor chip into the through-hole.

The bump of the first semiconductor chip may include solder, and forming the first solder pattern may include reflowing the solder by heating the solder.

Forming the first solder pattern may include inserting solder particles into the through-hole, and reflowing the solder particles by heating the solder particles.

The solder particles may be inserted into the through-hole by a screen printing method or a dotting method.

Mounting the first semiconductor chip on the package substrate may include bonding the first semiconductor chip to the package substrate with an adhesive layer therebetween.

The method of forming a semiconductor package may further include forming an upper conductive pattern on an upper surface of the package substrate, forming a mold layer covering the first semiconductor chip, forming a mold through-hole exposing the upper conductive pattern in the mold layer, locating a second semiconductor chip including a bump on the mold layer to insert the bump of the second semiconductor chip into the mold through-hole, and forming a second solder pattern electrically connecting the bump of the second semiconductor chip to the upper conductive pattern in the mold through-hole.

The method of forming a semiconductor package may further include bonding an external solder ball to the package substrate. Bonding the external solder ball may be performed independently of forming the first solder pattern.

According to example embodiments, a semiconductor package may include a package substrate including a substrate through-hole and a lower conductive pattern, the substrate through-hole penetrating the package substrate, and the lower conductive pattern on a bottom surface of the package substrate, a first semiconductor chip including a first bonding pad, the first bonding pad on a first surface of the first semiconductor chip, the first surface of the first semiconductor chip attached to an upper surface of the package substrate, and a first solder pattern in the substrate through-hole, the first solder pattern electrically connecting the first bonding pad to the lower conductive pattern.

The semiconductor package may further include a first bump attached to the first bonding pad, the first bump inserted into the substrate through-hole.

A height of the first bump may be smaller than a height of the substrate through-hole.

A height of the first bump may be substantially the same as a height of the first solder pattern.

The semiconductor package may further include an inner conductive pattern covering an inner sidewall of the substrate through-hole, the inner conductive pattern electrically connected to the lower conductive pattern.

The semiconductor package may further include a first bump attached to the first bonding pad, the first bump inserted into the substrate through-hole. The inner conductive pattern may be between the inner sidewall of the substrate through-hole and the first bump.

A height of the first solder pattern may be substantially smaller that a height of the inner conductive pattern.

The semiconductor package further includes an upper conductive layer pattern on the upper surface of the package substrate, a mold layer including a mold through-hole on the upper conductive layer pattern, the mold layer covering a sidewall of the first semiconductor chip and exposing the upper conductive layer pattern, a second semiconductor chip including a second bonding pad, the second bonding pad on a surface of the second semiconductor chip, the surface of the second conductor chip attached to the mold layer and a second surface of the first semiconductor chip, the second surface of the first semiconductor chip being opposite to the first surface of the first semiconductor chip, and a second solder pattern in the mold through-hole, the second solder pattern electrically connecting the second bonding pad to the upper conductive pattern.

A semiconductor package may include a first semiconductor package having the aforementioned structure, the first semiconductor package further including an upper conductive layer pattern on the upper surface of the package substrate and a mold layer on the upper conductive layer pattern, a second semiconductor package having the aforementioned structure, and a connection solder ball electrically connecting the upper conductive layer pattern of the first semiconductor package to the lower conductive pattern of the second semiconductor package. The mold layer may cover a sidewall of the first semiconductor chip and include a mold through-hole penetrating the mold layer,

### BRIEF DESCRIPTION OF THE DRAWINGS

The inventive concepts will become more apparent in view of the attached drawings and accompanying detailed description.

FIG. 1 is a plan view illustrating a semiconductor package according to example embodiments of the inventive concepts.

FIG. 2A is a cross-sectional view taken along a line II-IF of FIG. 1.

FIG. 2B is an enlarged view of a portion ‘P1’ of FIG. 2A.

FIGS. 3A, 3B, 4, 5, 6A, 6B, 6C, and 7 are cross-sectional views illustrating a method of forming a semiconductor package of FIG. 2A.

FIG. 8A is a cross-sectional view illustrating a semiconductor package according to example embodiments of the inventive concepts.

FIG. 8B is an enlarged view of a portion ‘P2’ of FIG. 8A.

FIG. 9 is a cross-sectional view illustrating a method of forming a semiconductor package of FIG. 8A.

FIG. 10A is a cross-sectional view illustrating a semiconductor package according to example embodiments of the inventive concepts.

FIG. 10B is an enlarged view of a portion ‘P3’ of FIG. 10A.

FIG. 11A is a cross-sectional view illustrating a semiconductor package according to example embodiments of the inventive concepts.

FIG. 11B is an enlarged view of a portion ‘P4’ of FIG. 11A.

FIG. 12 is a cross-sectional view illustrating a semiconductor package according to example embodiments of the inventive concepts.

FIGS. 13 and 14 are cross-sectional views illustrating a method of forming a semiconductor package of FIG. 12.

FIG. 15 is a cross-sectional view illustrating a semiconductor package according to example embodiments of the inventive concepts.

FIG. 16 is a perspective view illustrating an example of electronic devices including semiconductor packages according to example embodiments of the inventive concepts.

FIG. 17 is a system block diagram illustrating an example of electronic devices applied with semiconductor packages according to example embodiments of the inventive concepts.

FIG. 18 is a schematic block diagram illustrating an example of electronic systems including semiconductor packages according to example embodiments of the inventive concepts.

### DETAILED DESCRIPTION OF THE EMBODIMENTS

The inventive concepts will now be described more fully hereinafter with reference to the accompanying drawings, in which example embodiments of the inventive concepts are shown. The advantages and features of the inventive concepts and methods of achieving them will be apparent from the following example embodiments that will be described in more detail with reference to the accompanying drawings. It should be noted, however, that the inventive concepts are not limited to the following example embodiments, and may be implemented in various forms. Accordingly, the example embodiments are provided only to disclose the inventive concepts and let those skilled in the art know the category of the inventive concepts. In the drawings, example embodiments of the inventive concepts are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal example views of the inventive concepts. Accordingly, shapes of the example views may be modified according to manufacturing techniques and/or allowable errors. Therefore, the example embodiments of the inventive concepts are not limited to the specific shape illustrated in the example views, but may include other shapes that may be created according to manufacturing processes. Areas exemplified in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present inventive concepts. Example embodiments of the present inventive concepts explained and illustrated herein include their complementary counterparts. The same reference numerals or the same reference designators denote the same elements throughout the specification.

Moreover, example embodiments are described herein with reference to cross-sectional illustrations and/or plane illustrations that are idealized example illustrations. Accordingly, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

### First Example Embodiments

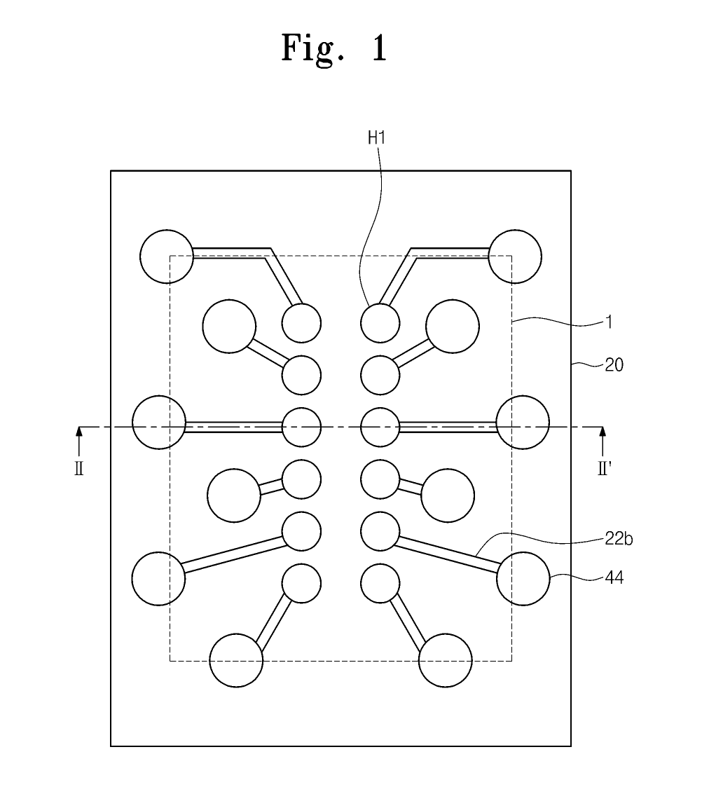

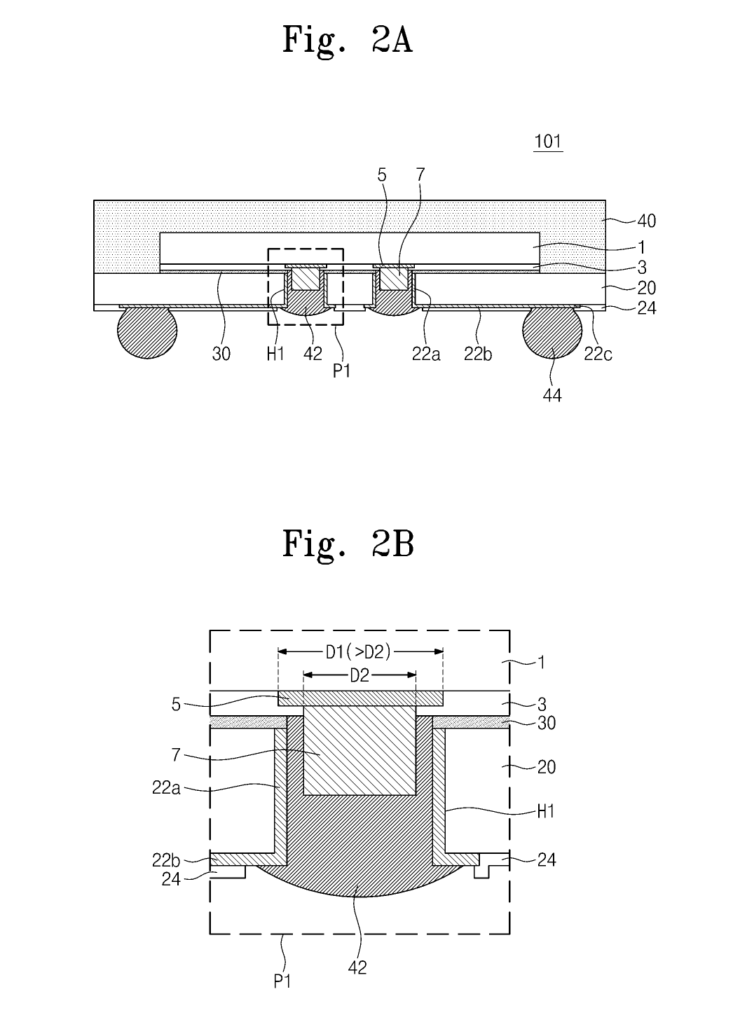

FIG. 1 is a plan view illustrating a semiconductor package according to example embodiments of the inventive concepts. FIG. 2A is a cross-sectional view taken along a line II-II′ of FIG. 1. FIG. 2B is an enlarged view of a portion ‘P1’ of FIG. 2A.

Referring to FIGS. 1, 2A, and 2B, a semiconductor chip 1 may be bonded to a package substrate 20 by an adhesive layer 30 in a semiconductor package 101 according to example embodiments. The package substrate 20 may include at least one substrate through-hole H1. At least one ball land 22c and at least one conductive line 22b may be disposed on a bottom surface of the package substrate 20. An inner sidewall of the substrate through-hole H1 may be covered by an inner conductive pattern 22a. The conductive line 22b may electrically connect the inner conductive pattern 22a to the ball land 22c. The conductive line 22b, the inner conductive pattern 22a, and the ball land 22c may be formed of the same conductive material. For example, the conductive line 22b, the inner conductive pattern 22a, and the ball land 22c may be formed of copper by a plating process. The conductive line 22b may be covered by a lower substrate insulating layer 24. The lower substrate insulating layer 24 may correspond to a solder resist layer. The lower substrate insulating layer 24 may be formed of a photosensitive photoresist layer. An external solder ball may be bonded to the ball land 22c.

At least one bonding pad 5 and a passivation layer 3 may be disposed under the semiconductor chip 1. The bonding pad 5 may be formed of a conductive material such as, for example, aluminum. The passivation layer 3 may be formed of, for example, a double layer of a silicon nitride layer and a polyimide layer. A bump 7 is disposed under the bonding pad 5. For example, the bump 7 may be formed of copper by a plating process. Even though not shown in the drawings, a diffusion preventing layer and a seed layer may be disposed between the bump 7 and the bonding pad 5. The diffusion preventing layer may be formed of at least one of titanium, titanium nitride, tantalum, and tantalum nitride. The seed layer may be formed of, for example, copper. The bump 7 is inserted in the substrate through-hole H1. A diameter D2 of the bump 7 is smaller than a diameter D1 of the inner conductive pattern 22a covering the inner sidewall of the substrate through-hole H1. Thus, the diameter D2 of the bump 7 is smaller than a diameter of the substrate through-hole H1.

A space between the bump 7 and the inner conductive pattern 22a is filled with a solder pattern 42. The solder pattern 42 may extend to fill the substrate through-hole H1. Additionally, the solder pattern 42 may also protrude to cover a portion of a bottom surface of the conductive line 22b. A protruded end of the solder pattern 42 may be higher than a bottom end of the external solder ball 44, the bottom end of the external solder ball being an end contacting the lower conductive pattern.

A mold layer 40 may cover a top surface and a sidewall of the semiconductor chip 1. The mold layer 40 may include a resin layer and a plurality of filler particles dispersed in the resin layer. The resin layer may include at least one polymer material. The filler particles may include a material such as silica and/or alumina.

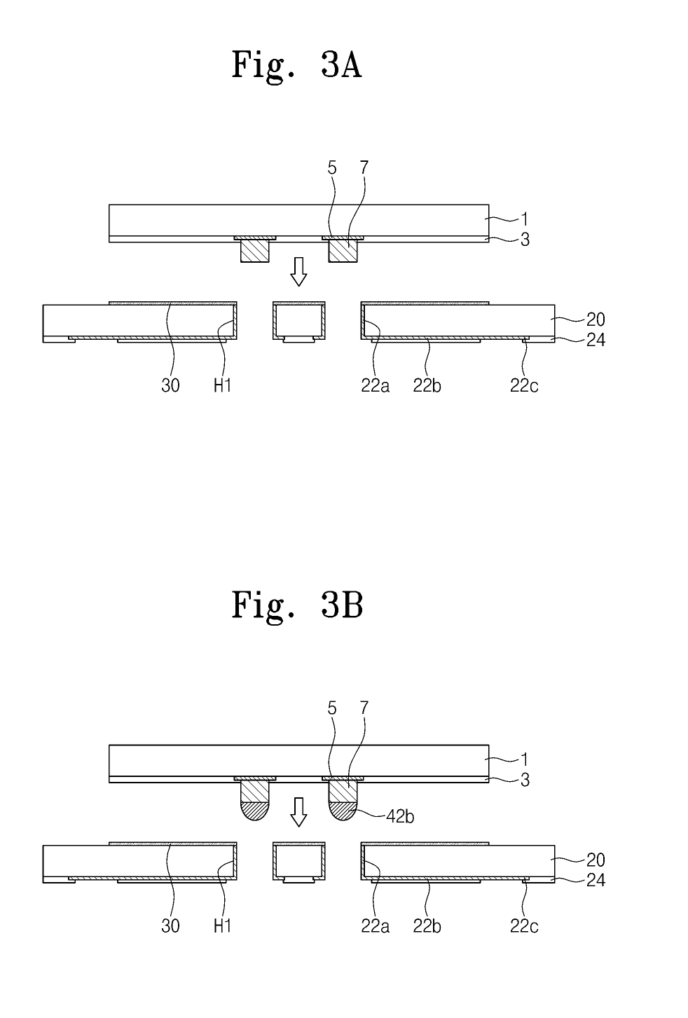

FIGS. 3A, 3B, 4, 5, 6A, 6B, 6C, and 7 are cross-sectional views illustrating a method of forming a semiconductor package of FIG. 2A.

Referring to FIG. 3A, a package substrate 20 may be prepared. The package substrate 20 may include substrate through-holes H1, inner conductive patterns 22a, conductive lines 22b, and ball lands 22c. A method of forming the package substrate 20 will be described in more detail. The substrate through-hole H1 may be formed in the package substrate 20. The substrate through-hole H1 may be formed using laser or a drill. After the substrate through-hole H1 is formed, a plating process may be performed to form the inner conductive pattern 22a, the conductive line 22b, and the ball land 22c. A lower substrate insulating layer 24 may be formed to cover the conductive line 22b and to expose the inner conductive pattern 22a and the ball land 22c.

Referring again to FIG. 3A, an adhesive layer 30 may be formed on the package substrate 20. The adhesive layer 30 may be an adhesive or a double-sided tape. A semiconductor chip 1 including bonding pads 5 and bumps 7 may be located over the package substrate 20. The bump 7 may be formed of copper. According to example embodiments as illustrated in FIG. 3B, in the semiconductor chip 1, a solder bump 42b may be bonded to and extended or protruded from a bottom surface of the bump 7, which is formed of copper,.

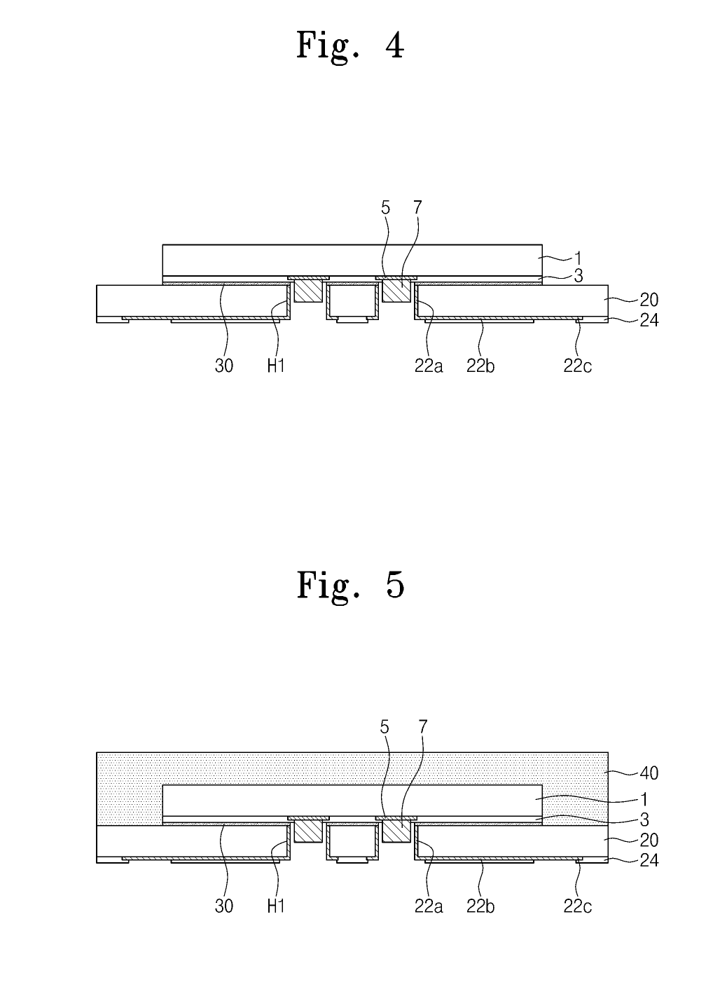

Referring to FIG. 4, the semiconductor chip 1 may be located such that the bump 7 corresponds to a position of the substrate through-hole H1. The bump 7 may be inserted into the substrate through-hole H1 while the semiconductor chip 1 may be bonded to the top surface of the package substrate 20. The bump 7 may partially fill the substrate through-hole H1. The bump 7 may be spaced apart from the inner conductive pattern 22a in the substrate through-hole H1.

Referring to FIG. 5, a mold layer 40 may be formed on the package substrate 20 to cover a top surface and a sidewall of the semiconductor chip 1.

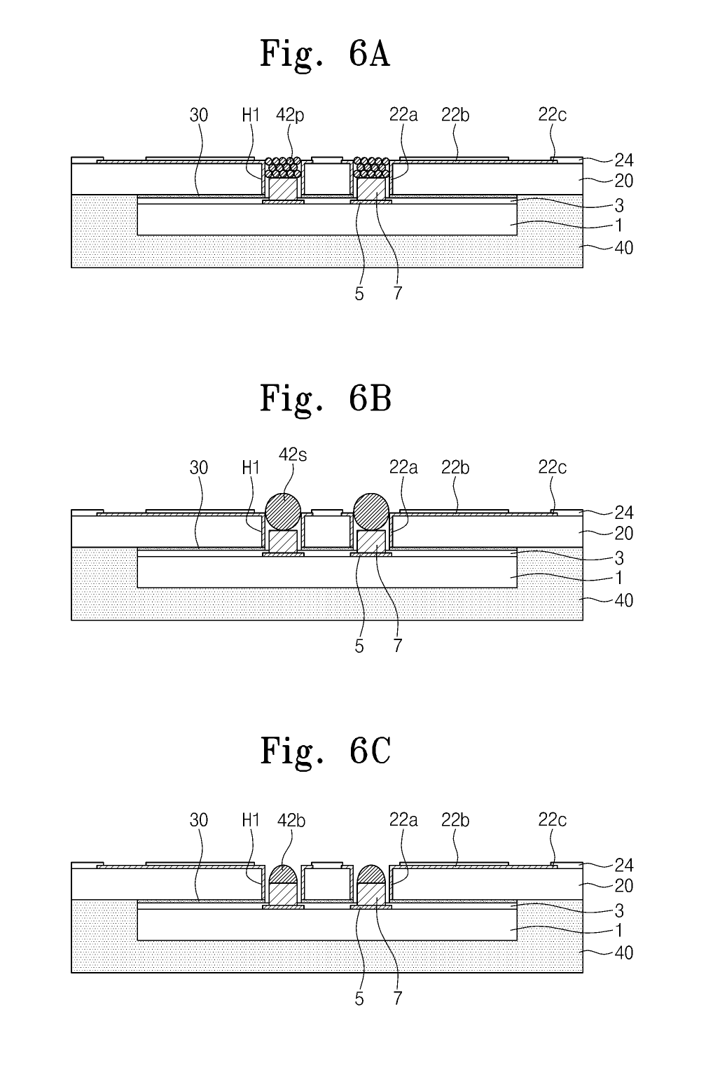

Referring to FIG. 6A, the package substrate 20 may be overturned with its bottom surface facing upward. A plurality of solder particles 42p may be inserted into the substrate through-hole H1. The solder particles 42p may be inserted using a screen printing method or a dotting method. According to example embodiments, one small solder ball 42s may be inserted into the substrate through-hole H1, as illustrated in FIG. 6B. According to example embodiments, if the solder bump 42b is bonded to the copper bump 7 as described above with reference to FIG. 3B, the bump 7 and the solder bump 42b may be inserted into the substrate through-hole H1 as illustrated in FIG. 6C. The solder particles 42p, the small solder ball 42s, and the solder bump 42b may be formed of at least one metal selected from a group consisting of tin (Sn), lead (Pb), and silver (Ag). A melting point of the solder particles 42p, the small solder ball 42s, and the solder bump 42b may be within a range of about 180 degrees Celsius to about 250 degrees Celsius.

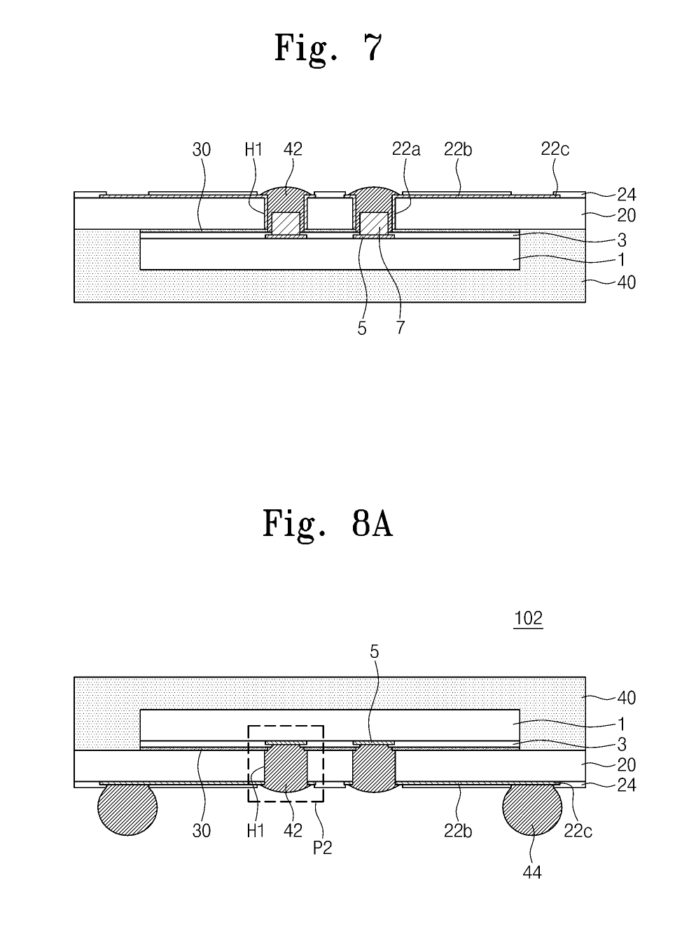

Referring to FIG. 7, heat of a temperature equal to or greater than the melting point of the solder particles 42p, the small solder ball 42s, and the solder bump 42b may be applied to completely melt the solder particles 42p, the small solder ball 42s, and the solder bump 42b, such that the solder particles 42p, the small solder ball 42s, and the solder bump 42b may be reflowed. Thus, the melted solder solution may flow down by gravity to fill a space between the bump 7 and the inner conductive pattern 22a and to fill the substrate through-hole H1. Thereafter, the temperature may be reduced to harden the solder solution. As a result, a solder pattern 42 may be formed. If the bump 7 is formed of copper, however, the bump 7 may not be melted in the reflow process because of a high melting point (e.g., about 1083 degrees Celsius) of copper.

Next, the external solder ball 44 of FIG. 2A may be bonded to the ball land 22c to form the semiconductor package illustrated in FIG. 2A. A process temperature and/or a process time of a reflow process for bonding of the external solder ball 44 may be lower and/or shorter than a process temperature and/or a process time of the reflow process for the formation of the solder pattern 42. Thus, the solder pattern 42 may not be completely melted and may not flow when the external solder ball 44 is bonded to the ball land 22c.

Next, a singulation process may be performed for separating unit semiconductor packages from each other.

In the semiconductor package 101 according to these first example embodiments, the bump 7 may be inserted in the substrate through-hole H1 of the package substrate 20. Thus, a thickness of the semiconductor package 101 may be reduced by at least a height of the bump 7. Additionally, because an empty space does not exist between the semiconductor chip 1 and the package substrate 20, the semiconductor package 101 may not need a conventional underfill resin layer. Thus, the processes for forming the semiconductor package 101 may be simplified. Furthermore, a wire bonding method and/or a flip chip bonding method may not be applied to the formation of the semiconductor package 101. Thus, it may be possible to resolve short problems between wires or between solder balls disposed between a semiconductor chip and a package substrate. As a result, yield/reliability of the semiconductor package 101 may be improved.

### Second Example Embodiments

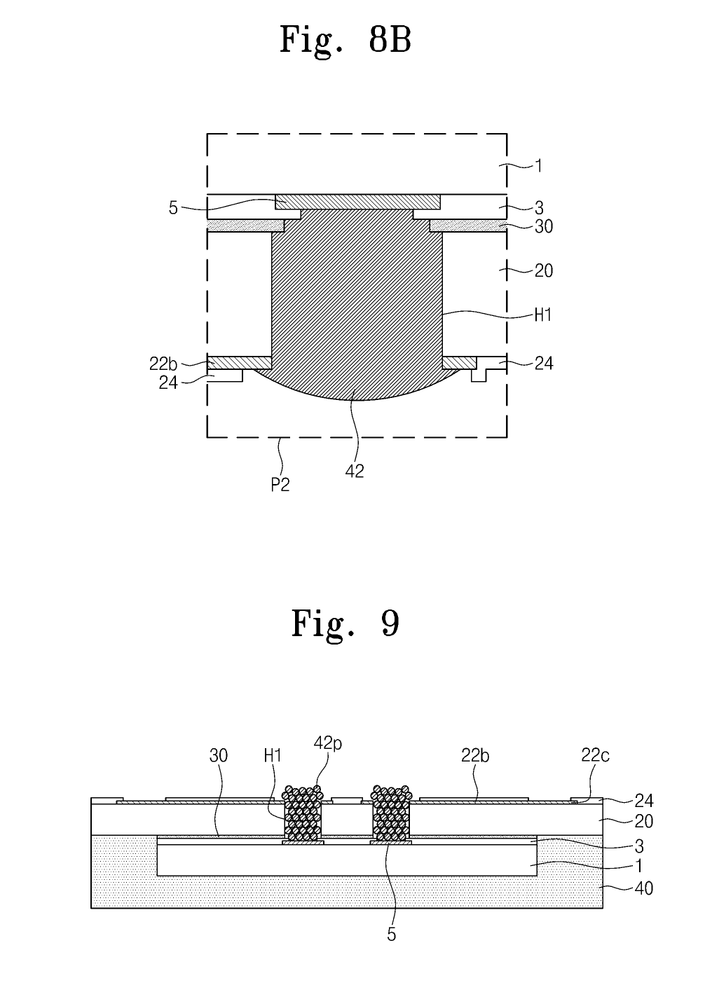

FIG. 8A is a cross-sectional view illustrating a semiconductor package according to example embodiments of the inventive concepts. FIG. 8B is an enlarged view of a portion ‘P2’ of FIG. 8A.

Referring to FIGS. 8A and 8B, a semiconductor package 102 according to these second example embodiments may not include the inner conductive pattern 22a covering an inner sidewall of the through-hole H1 and the bump 7. The through-hole H1 may be filled with only a solder pattern 42. The solder pattern 42 may be in contact with the inner sidewall of the through-hole H1 and the conductive line 22b simultaneously. Other elements of the semiconductor package 102 may be the same as/similar to the elements corresponding thereto in the first embodiment.

FIG. 9 is a cross-sectional view illustrating a method of forming a semiconductor package of FIG. 8A.

According to an example embodiment, the semiconductor package 102 may be formed where the bump 7 of FIGS. 6A to 6C is formed of solder, not copper, in the formation method described with reference to FIGS. 3A, 3B, 4, 5, 6A, 6B, 6C, and 7. According to other example embodiment, referring to FIG. 9, a semiconductor chip 1 may include a bonding pad 5 but may not include the bump 7 formed of copper. After the semiconductor chip 1 may be bonded to the package substrate 20 such that the bonding pad 5 overlaps with the substrate through-hole H1, the substrate through-hole H1 may be filled with solder particles 42p. Thereafter, the reflow process may be performed to form the solder pattern 42. Other elements and other processes of these example embodiments may be the same as/similar to the elements and the processes corresponding thereto in the first embodiment.

### Third Example Embodiments

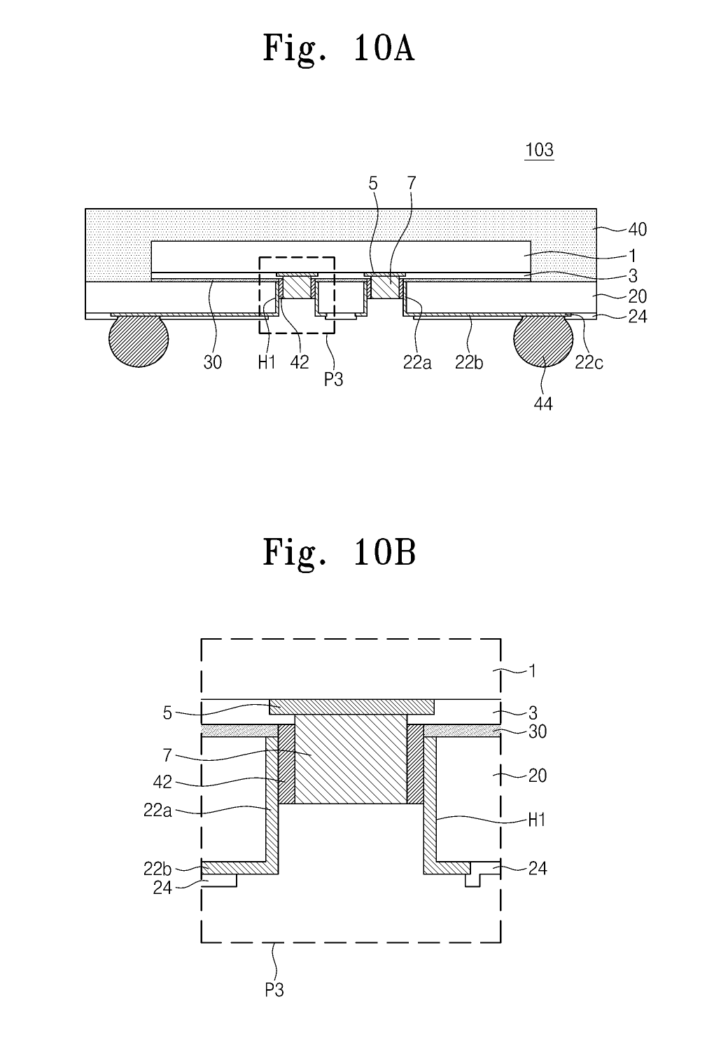

FIG. 10A is a cross-sectional view illustrating a semiconductor package according to example embodiments of the inventive concepts. FIG. 10B is an enlarged view of a portion ‘P3’ of FIG. 10A.

Referring to FIGS. 10A and 10B, a solder pattern 42 may fill only a space between the bump 7 and the inner conductive pattern 22a in a semiconductor package 103 according to these third example embodiments. For example, the solder pattern 42 may not completely fill the substrate through-hole H1. Additionally, the solder pattern 42 may not be in direct contact with the conductive line 22b. If the amounts of the solder particles 42p, the small solder ball 42s, and the solder bump 42b are small in the processes described with reference to FIGS. 6A to 6C, the semiconductor package 103 according to the present may be formed. Other elements and other processes of these third example embodiments may be the same as/similar to the elements and the processes corresponding thereto in the first embodiment.

### Fourth Example Embodiments

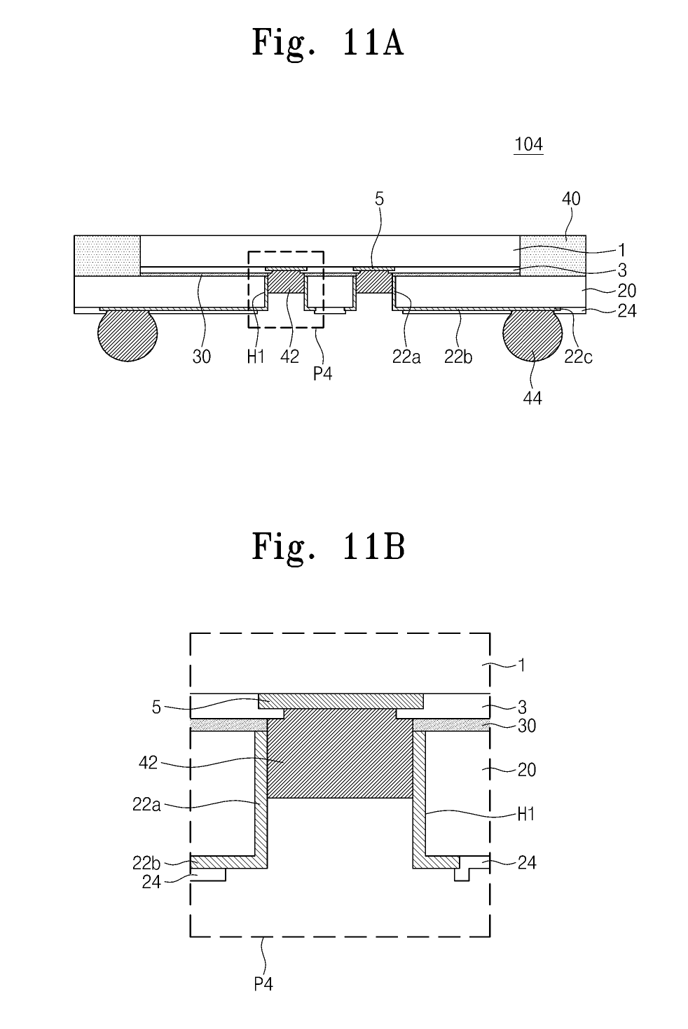

FIG. 11A is a cross-sectional view illustrating a semiconductor package according to example embodiments of the inventive concepts. FIG. 11B is an enlarged view of a portion ‘P4’ of FIG. 11A.

Referring to FIGS. 11A and 11B, a mold layer 40 may cover the sidewall of the semiconductor chip 1 but may not cover the top surface of the semiconductor chip 1 in a semiconductor package 104 according to these fourth example embodiments. Also, the semiconductor package 104 may not include the bump 7. A solder pattern 42 may partially fill the substrate through-hole H1 and may be in contact with the inner conductive pattern 22a. Other elements and other processes of these fourth example embodiments may be the same as/similar to the elements and the processes corresponding thereto in the second example embodiments.

### Fifth Example Embodiments

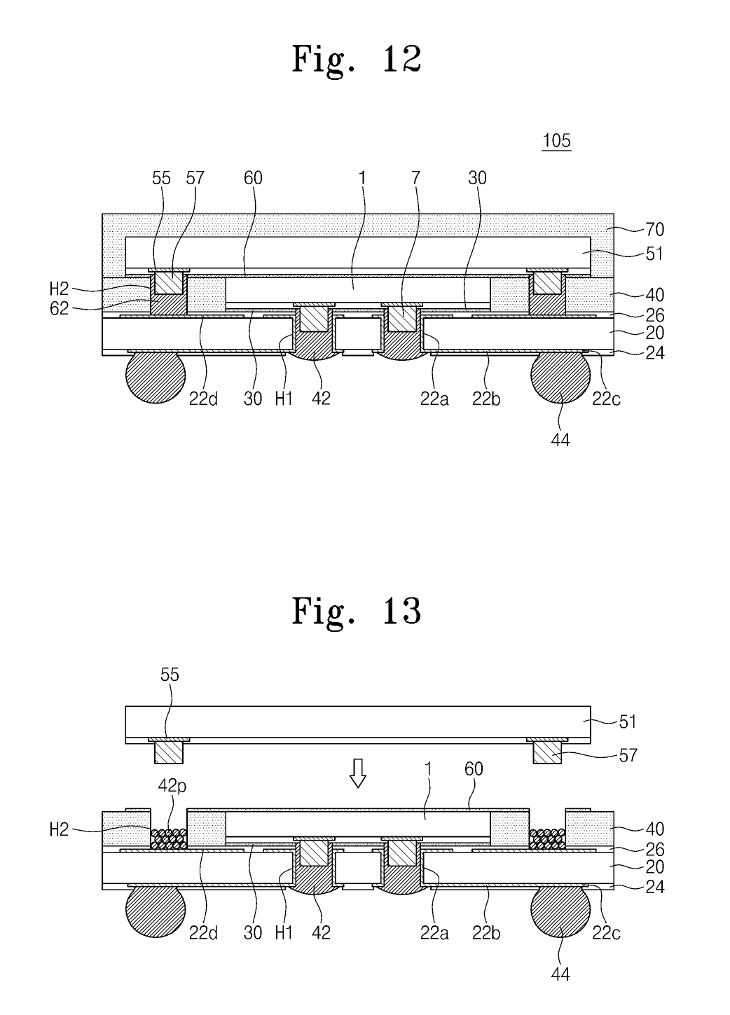

FIG. 12 is a cross-sectional view illustrating a semiconductor package according to example embodiments of the inventive concepts.

Referring to FIG. 12, in a semiconductor package 105 according to these fifth example embodiments, a first semiconductor chip 1 may be bonded to the top surface of the package substrate 20 by a first adhesive layer 30, and a first bump 7 of the first semiconductor chip 1 may be inserted in the substrate through-hole H1 of the package substrate 20. A first solder pattern 42 may be disposed in the substrate through-hole H1 to electrically connect the first bump 7 to the conductive line 22b. An upper conductive pattern 22d may be disposed on the top surface of the package substrate 20, and an upper substrate insulating layer 26 may cover a portion of the upper conductive pattern 22d. A first mold layer 40 may cover a sidewall of the first semiconductor chip 1. A mold through-hole H2 may be formed in the first mold layer 40 to expose the upper conductive pattern 22d. A second semiconductor chip 51 may be bonded to the top surface of the first semiconductor chip 1 by a second adhesive layer 60. The second semiconductor chip 51 may include a second bonding pad 55 and a second bump 57 protruding from the second bonding pad 55. The second bump 57 is inserted in the mold through-hole H2. A second solder pattern 62 is disposed in the mold through-hole H2 to electrically connect the second bump 57 to the upper conductive pattern 22d. A second mold layer 70 may cover a top surface and a sidewall of the second semiconductor chip 51. Other elements of the semiconductor package 105 may be the same as/similar to the elements corresponding thereto in the first example embodiments. Similarly to FIG. 8, the mold through-hole H2 may be filled with the second solder pattern 62 without the second bump 57.

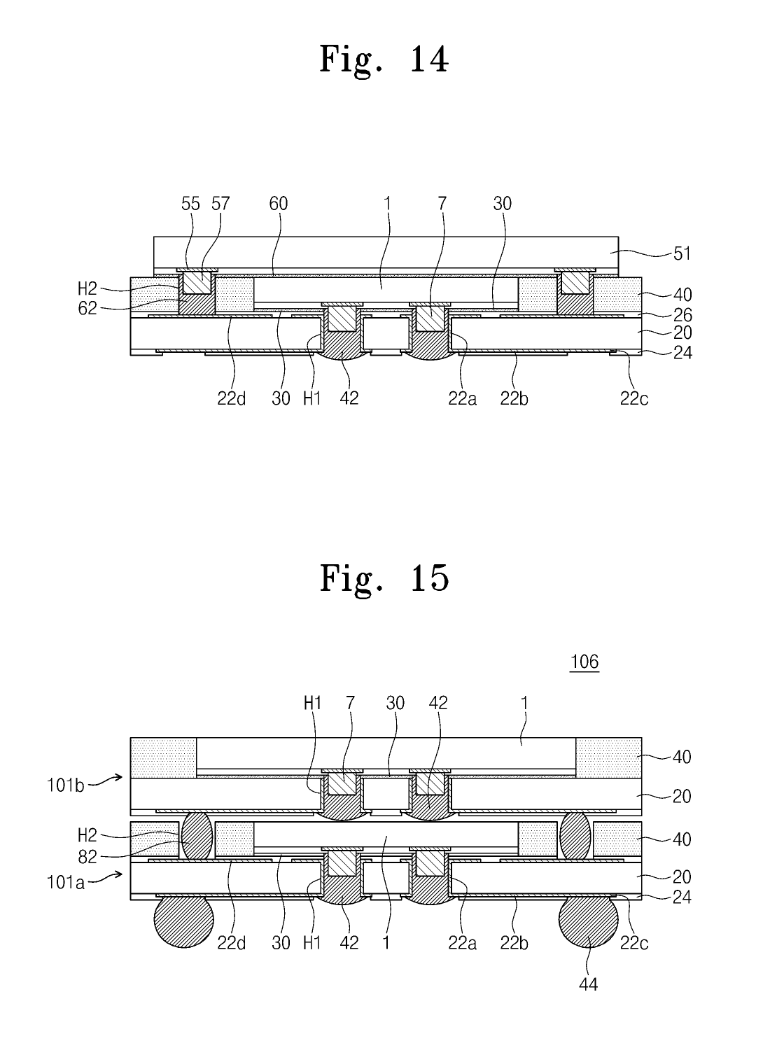

FIGS. 13 and 14 are cross-sectional views illustrating a method of forming a semiconductor package of FIG. 12.

Referring to FIG. 13, after the first semiconductor chip 1 including the substrate through-hole H1 is bonded on the package substrate 20 and then the first solder pattern 42 and the first mold layer 40 are formed, similarly to FIG. 7, the first mold layer 40 may be patterned to form the mold through-hole H2 exposing the upper conductive pattern 22d. Solder particles 42p may be inserted into the mold through-hole H2, and the second adhesive layer 60 may be formed on the first mold layer 40 and the top surface of the first semiconductor chip 1. The second bump 57 may be inserted into the mold through-hole H2 while the second semiconductor chip 51 is bonded to the second adhesive layer 60.

Referring to FIG. 14, the solder particles 42p may be reflowed by a heating process of a temperature equal to or greater than the melting point of the solder particles 42p, thereby forming the second solder pattern 62.

Next, referring to FIG. 12, the second mold layer 70 may be formed to cover the sidewall and the top surface of the second semiconductor chip 51, and the external solder ball 44 may be bonded to the ball land 22c. Other processes of these fifth example embodiments may be the same as/similar to the processes corresponding thereto in the second example embodiments.

### Sixth Example Embodiments

FIG. 15 is a cross-sectional view illustrating a semiconductor package according to example embodiments of the inventive concepts.

Referring to FIG. 15, a semiconductor package 106 according to these sixth example embodiments may have a package-on-package structure including sequentially-stacked first and second semiconductor packages 101a and 101b. Each of the first and second semiconductor packages 101a and 101b may be similar to the semiconductor package 101 of the first embodiment. The first and second semiconductor packages 101a and 101b may be electrically connected to each other through a connection solder ball 82. The connection solder ball 82 may be disposed in a mold through-hole H2, which is formed in the mold layer 40 of the first semiconductor package 101a.

Other elements of the semiconductor package 106 may be the same as/similar to the elements corresponding thereto in the first example embodiments.

The first to sixth example embodiments described above may be combined in various forms under a non-contradictable condition.

The semiconductor package techniques mentioned above may be applied to various kinds of semiconductor devices and package modules including them.

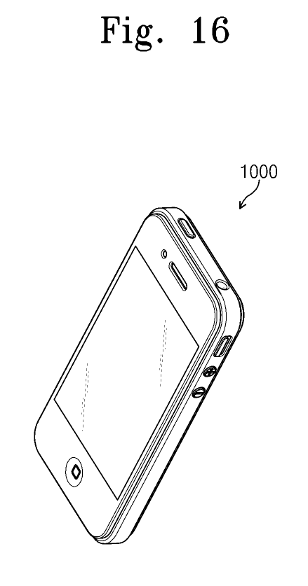

FIG. 16 is a perspective view illustrating an example of electronic devices including semiconductor packages according to example embodiments of the inventive concepts.

Referring to FIG. 16, the semiconductor packages according to embodiments of the inventive concept may be applied to an electronic device 1000 such as a smart phone. Because the semiconductor packages according to example embodiments of the inventive concepts have excellent characteristics in size reduction and performance, they may be advantageous to lightness, thinness, shortness, and smallness of the electronic device 1000 performing various functions simultaneously. The electronic devices according to the inventive concepts are not limited to the smart phone of FIG. 16. According to other example embodiments, the electronic devices according to the inventive concepts may be realized as one of various electronic devices such as a mobile electronic device, a laptop computer, a portable computer, a portable multimedia player (PMP), a MP3 player, a camcorder, a web tablet, a wireless phone, a navigation, and a personal digital assistant (PDA).

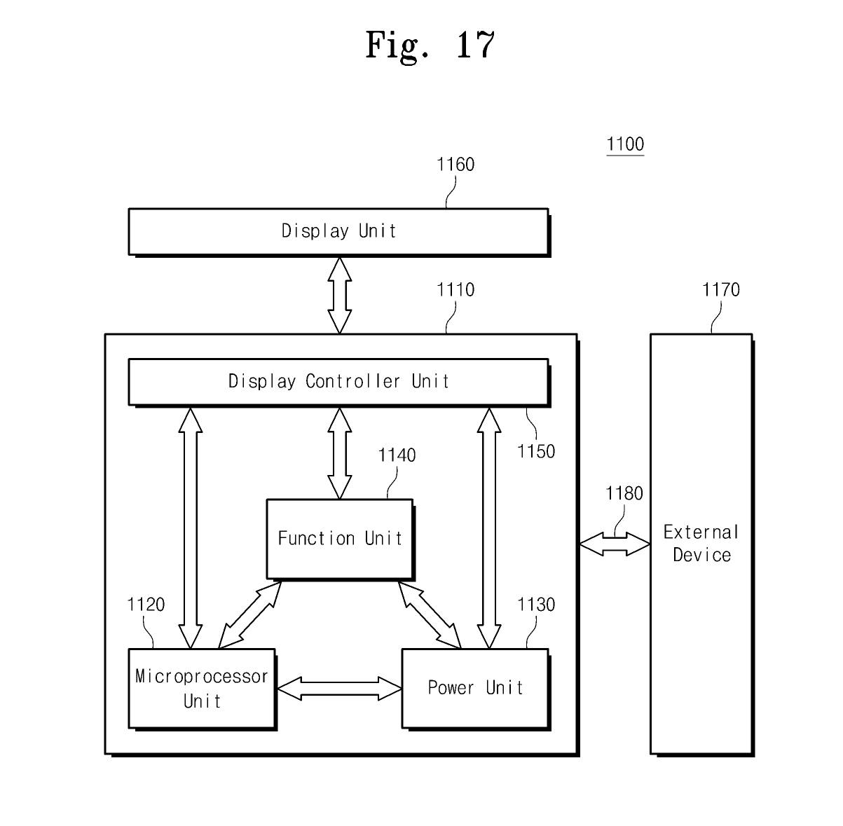

FIG. 17 is a system block diagram illustrating an example of electronic devices applied with semiconductor packages according to example embodiments of the inventive concepts.

Referring to FIG. 17, the aforementioned semiconductor packages 101 to 106 may be applied to an electronic device 1100 according to other example embodiments. The electronic device 1100 may include a body 1110, a microprocessor unit 1120, a power unit 1130, a function unit 1140, and a display controller unit 1150. The body 1110 may include a set board formed of a printed circuit board. The microprocessor unit 1120, the power unit 1130, the function unit 1140, and the display controller unit 1150 may be mounted on the body 1110.

The power unit 1130 may be provided with a desired (or alternatively, a predetermined) voltage from an external battery (not shown) and then may divide the desired (or alternatively, a predetermined) voltage into various desired voltage levels. The power unit 1130 may provide the divided voltage levels to the microprocessor unit 1120, the function unit 1140, and the display controller unit 1150.

The microprocessor unit 1120 may be provided with the voltage from the power unit 1130 and then may control the function unit 1140 and a display unit 1160. The function unit 1140 may perform various functions of the electronic device 1100. For example, if the electronic device 1100 is a mobile phone, the function unit 1140 may include various elements capable of performing mobile phone functions such as dialing, image output of the display unit 1160 by communication with an external device 1170, and voice output of a speaker. If the electronic device 1100 includes a camera, the function unit 1140 may be a camera image processor. For example, if the electronic device 1100 is connected to a memory card for extending memory capacity, the function unit 1140 may be a memory card controller. The function unit 1140 may communicate with the external device 1170 through a wireless or wired communication unit 1180. For example, if the electronic device 1100 needs a universal serial bus (USB) for expanding functions, the function unit 1140 may be an interface controller. The semiconductor packages 101 to 106 according to the aforementioned example embodiments may be applied to at least one of the microprocessor unit 1120 and the function unit 1140.

The semiconductor package technologies described above may be applied to an electronic system.

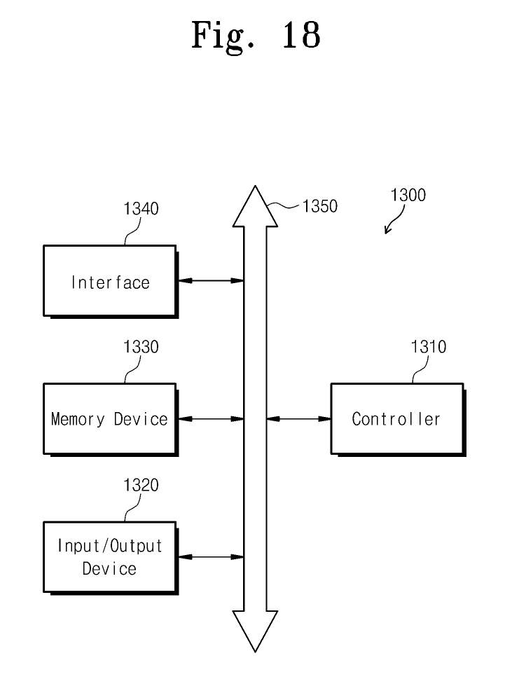

FIG. 18 is a schematic block diagram illustrating an example of electronic systems including semiconductor packages according to example embodiments of the inventive concepts.

Referring to FIG. 18, an electronic system 1300 may include a controller 1310, an input/output device 1320, and a memory device 1330. The controller 1310, the input/output device 1320, and the memory device 1330 may be combined with each other through a bus 1350. The bus 1350 may correspond to a path through which electrical signals are transmitted. For example, the controller 1310 may include at least one of a microprocessor, a digital signal processor, a microcontroller and other logic devices. The other logic devices may have a similar function to any one of the microprocessor, the digital signal processor and the microcontroller. The controller 1310 and the memory device 1330 may include the semiconductor packages according to example embodiments of the inventive concepts. The input/output device 1320 may include a keypad, a keyboard and/or a display unit. The memory device 1330 is a device storing data. The memory device 1330 may store data and/or command executed or to be executed by the controller 1310. The memory device 1330 may include a volatile memory device and/or a non-volatile memory device (e.g., of a flash memory device). The flash memory device may be realized as a solid state disk (SSD). In this case, the electronic system 1300 may stably store massive data in the memory device 1330. The electronic system 1300 may further include an interface unit 1340 that may transmit electrical data to a communication network or may receive electrical data from the communication network. The interface unit 1340 may operate in a wired or wireless manner. For example, the interface unit 1340 may include an antenna or a cable/wireless transceiver. Although not shown in the drawings, an application chipset and a camera image processor (CIS) may further be provided to the electronic system 1300.

According to example embodiments of the inventive concepts, the bump may be inserted into the through-hole of the package substrate. As a result, the thickness of the semiconductor package may be reduced by at least the height of the bump. Additionally, because an empty space does not exist between the semiconductor chip and the package substrate, the semiconductor package does not need a conventional underfill resin layer. Thus, the processes of forming the semiconductor package may be simplified.

While the inventive concepts has been described with reference to example embodiments, it will be apparent to those skilled in the art that various changes and modifications may be made without departing from the spirit and scope of the inventive concepts. Therefore, it should be understood that the above embodiments are not limiting, but illustrative. Thus, the scope of the inventive concepts is to be determined by the broadest permissible interpretation of the following claims and their equivalents, and shall not be restricted or limited by the foregoing description.

1. A semiconductor package comprising:
a package substrate including at least one through-hole and a lower conductive pattern, the through-hole penetrating the package substrate, and the lower conductive pattern on a bottom surface of the package substrate;
a first semiconductor chip mounted on the package substrate, the first semiconductor chip including a bonding pad; and
a first solder pattern disposed in the through-hole, the first solder pattern electrically connecting the bonding pad to the lower conductive pattern.

2. The semiconductor package of claim 1, wherein the first semiconductor chip further includes a bump attached to the bonding pad and inserted in the through-hole.

3. The semiconductor package of claim 2, wherein a diameter of the through-hole is greater than a diameter of the bump in the through-hole.

4. The semiconductor package of claim 2, wherein the lower conductive pattern extends to cover an inner sidewall of the through-hole, and the first solder pattern fills a space between the lower conductive pattern and the bump.

5. The semiconductor package of claim 1, wherein the first solder pattern is in contact with both an inner sidewall of the through-hole and the lower conductive pattern.

6. The semiconductor package of claim 1, further comprising:
a mold layer covering at least a sidewall of the first semiconductor chip.

7. The semiconductor package of claim 6, wherein
the mold layer includes a mold through-hole penetrating there through, the package substrate further includes an upper conductive pattern on a top surface of the package substrate and exposed by the mold through-hole, and
the semiconductor package further includes,
a second semiconductor chip on the first semiconductor chip, the second semiconductor chip including a second bonding pad, the second bonding pad overlapping with the mold through-hole, and
a second solder pattern in the mold through-hole, the second solder pattern electrically connecting the second bonding pad to the upper conductive pattern in the mold through-hole.

8. The semiconductor package of claim 7, wherein
the second semiconductor chip further includes a bump contacting both the second bonding pad and the second solder pattern, and the bump of the second semiconductor chip is inserted in the mold through-hole.

9. The semiconductor package of claim 1, further comprising:
an adhesive layer between the package substrate and the first semiconductor chip.

10. The semiconductor package of claim 1, further comprising:
an external solder ball bonded to the lower conductive pattern,
wherein a protruded end of the first solder pattern is higher than a bottom end of the external solder ball, the bottom end of the external solder ball being an end contacting the lower conductive pattern.

11. A package on package device comprising:
a first semiconductor package including a first package substrate and a first semiconductor chip on the first package substrate, the first package substrate including a first through-hole, and the first semiconductor chip including a first bump inserted in the first through-hole; and
a second semiconductor package stacked on the first semiconductor package, the second semiconductor package including a second package substrate and a second semiconductor chip on the second package substrate, the second package substrate including a second through-hole, and the second semiconductor chip including a second bump inserted in the second through-hole.

12.-20. (canceled)

21. A semiconductor package comprising:
a package substrate including a substrate through-hole and a lower conductive pattern, the substrate through-hole penetrating the package substrate, and the lower conductive pattern on a bottom surface of the package substrate;
a first semiconductor chip including a first bonding pad, the first bonding pad on a first surface of the first semiconductor chip, the first surface of the first semiconductor chip attached to an upper surface of the package substrate; and
a first solder pattern in the substrate through-hole, the first solder pattern electrically connecting the first bonding pad to the lower conductive pattern.

22. The semiconductor package of claim 21, further comprising:
a first bump attached to the first bonding pad, the first bump inserted into the substrate through-hole.

23. The semiconductor package of claim 22, wherein a height of the first bump is less than a height of the substrate through-hole.

24. The semiconductor package of claim 22, wherein a height of the first bump is substantially the same as a height of the first solder pattern.

25. The semiconductor package of claim 21, further comprising:
an inner conductive pattern covering an inner sidewall of the substrate through-hole, the inner conductive pattern electrically connected to the lower conductive pattern.

26. The semiconductor package of claim 25, further comprising:
a first bump attached to the first bonding pad, the first bump inserted into the substrate through-hole, and wherein
the inner conductive pattern is between the inner sidewall of the substrate through-hole and the first bump.

27. The semiconductor package of claim 25, wherein a height of the first solder pattern is less than a height of the inner conductive pattern.

28. The semiconductor package of claim 21, further comprising:
an upper conductive layer pattern on the upper surface of the package substrate;
a mold layer including a mold through-hole on the upper conductive layer pattern, the mold layer covering a sidewall of the first semiconductor chip and exposing the upper conductive layer pattern;
a second semiconductor chip including a second bonding pad, the second bonding pad on a surface of the second semiconductor chip, the surface of the second conductor chip attached to the mold layer and a second surface of the first semiconductor chip, the second surface of the first semiconductor chip being opposite to the first surface of the first semiconductor chip; and
a second solder pattern in the mold through-hole, the second solder pattern electrically connecting the second bonding pad to the upper conductive pattern.

29. A semiconductor package comprising:
a first semiconductor package according to claim 21, the first semiconductor package further including,
an upper conductive layer pattern on the upper surface of the package substrate; and
a mold layer on the upper conductive layer pattern, the mold layer covering a sidewall of the first semiconductor chip and including a mold through-hole penetrating the mold layer;
a second semiconductor package according to claim 21; and
a connection solder ball electrically connecting the upper conductive layer pattern of the first semiconductor package to the lower conductive pattern of the second semiconductor package.
